(19) United States
(12) Patent Application Publication
(10) Pub. No.: US 2016/0007475 A1
(43) Pub. Date: Jan. 7, 2016

(54) METHOD OF PRINTING ELECTRONIC SYSTEMS ON TEXTILE SUBSTRATES

(71) Applicant: D.R.E.T. TECHNOLOGY SAGL, Chiasso (CH)

(72) Inventor: Davide ZANESI, Lecco (IT)

(21) Appl. No.: 14/771,590

(22) PCT Filed: Mar. 4, 2014
(86) PCT No.: PCT/IB2014/000261

§ 371 Date: Aug. 31, 2015

(30) Foreign Application Priority Data
Mar. 7, 2013 (IT) MI2013A000350
Aug. 7, 2013 (IT) MI2013A001362

(51) Int. Cl. H05K 3/00; B41J 2/01; H05K 1/18; H05K 1/09; H05K 1/03; B41F 15/00; H05K 1/02

(52) U.S. Cl. CPC H05K 3/0064; B41F 15/00; B41J 2/01; H05K 1/0283; H05K 1/0271; H05K 1/09; H05K 1/038; H05K 1/0326; H05K 1/189; H05K 2201/0145; H05K 2201/0323; H05K 2201/08

(57) ABSTRACT

The present invention relates to the very innovative field of smart textiles. More particularly the present invention discloses an innovative process for screen printing of textile substrates, by means of primers, for depositing on said substrates dielectric, conductive, resistive, magnetic, electroluminescent materials and many others.

### FIELD OF THE INVENTION

The present invention relates to very innovative field of the smart textiles. More particularly the present invention relates to a method of printing electronic systems on textile fabrics.

The field of production of smart textiles is very innovative and has a great economic interest. The concept of integrating into a textile fabric different elements, broadening its use, is a technological target indicating the way for further progress. These factors make the smart textiles particularly interesting for developing new markets and meeting the demand of innovation and economic savings being the core of the present and future development. Indeed there is a steadily increasing interest for more performing systems, being at the same time economic and appearing a visible sign of technological progress. Moreover, the demand is for integrated systems, requiring the least possible space and optimising comfort, design and functionality.

### BACKGROUND OF THE INVENTION

The field of smart textiles is a clear example of the foregoing observations, more particularly the term smart textiles means a textile fabric produced by advanced technologies, that can meet the requirements of the wearer and/or user. For instance it is really an outstanding idea to develop textiles that can be used in up to now unforeseen ways, see e.g. “the programmers should start to project networks that are applicable directly into individuals and their life, wearable computers and smart textiles” (William J. Mitchell, interview by A. Dagnino, insert Technology & Science p. 11, Sole 24 Ore of 24.02.2004). The state of the art definition of smart textiles comprises a very broad range of textile fabrics, such as no-tear fabrics for accident prevention systems, medicated fabrics containing substances integrated among the fibers, that are released when contacted with the human skin for clinical or aesthetic purposes, thermoregulating fabrics, anti-UV radiation fabrics, and in the very last generation, T-shirts with integrated sensors, that can monitor e.g. blood pressure, body temperature, heartbeat and other parameters of patients. It is clear that fabrics, either worn by a person or used for articles of any kind, are the subject of a great number of researches, technical and scientific surveys and the like. More particularly, the field of the present invention consists of the “electrotextiles”, i.e. the electronic molding of textiles, in order to obtain a textile fabric with a plurality of functions, adapted to carry out, through printed electronic systems, the functions of a conventional electronic circuit.

More particularly, in the field of the electrotextiles, that may be worn by persons or used for other purposes, it is known that the production of a textile fabric provided with a printed electronic circuit, involves many problems either in the manufacturing stage or in the subsequent practical use, that frequently hindered the implementation of such projects, either for economic reasons or for objective feasibility limits. Moreover the practical actual use of the fabric thus obtained, was found to be impossible in some circumstances due to the poor quality of the final product.

The printed electronic circuits generally comprise a number of tracks of conductive material printed on a proper insulating support. These tracks are intended to connect to one another the components of the electronic circuit, or may even constitute the actual electronic element. The basic material generally comprises a base element, e.g. of silicium, which is a rigid support having a standard thickness of about 1.6 mm of insulating material, on which a blade of copper, silver or aluminium having a thickness varying from 10 to 35 microns is applied. The insulating materials generally used for printed electronic circuits are phenolic resin, if medium to low performances are required and vetronite if higher performances are necessary. One of the major drawbacks of using the electronic circuits now employed for electronic boards or even for rfid antennas, is that said electronic circuits are made of rigid and poorly versatile materials. Obviously this drawback reduces the applicability of these devices. Indeed, although a printed electronic circuit may be of reduced dimensions, it is always difficult to apply or insert it on/in some articles just because of its structural stiffness, clearly causing also a greater brittleness of the article. This feature therefore makes the electronic circuits particularly difficult to be handled, especially in the environment of the so-called smart textiles.

More particularly, this limit is facing the problems always found by researchers when looking at smart fibers: indeed textile fabrics, in view of their features, are often very flexible and subject to complex mechanical stresses, which they very well resist to. On the contrary the electronic components required to make these technological textiles, are solid, poorly flexible and delicate when in use.

Many parts of electronic products are generally made of inorganic materials or metals, including semi-conductors, therefore most materials and components are solid or enclosed in solid containers.

Since on the contrary most textile fabrics consist of short fibres or long interwoven fibers, the form of a standard fabric is therefore thin or very thin and very flexible, and the form of the fibres and consequently of the fabric may be stretched or compressed, and said textile forming fibres may be at least partially stretched when a force is applied thereto.

When the object is to integrate electronic components and textile fabrics, the stress exerted on the final product is focused on the physical border between the flexible and solid parts and this particular area under stress has a negative impact on the reliability of the product in the actual use, because this is the region most prone to failure.

Moreover, one should not neglect the comfort factor generally characterizing a generic fabric, more particularly for articles of clothing; clearly the fact of integrating solid elements, e.g. inside garments, these solid parts reduce considerably comfort of the article and the useful life of the material, as they are most prone to wear relative to a normal fabric.

Another element to be carefully considered is the electric conductance. The electronic parts of the mentioned components, generally consist of conductive or semiconductive materials, and are energized by the electric current flowing from the feeding source to the component. Moreover one should also take into account that most fibres are of non conductive nature, so that the fiber resistivity is generally very high. In other words, the main problem to be solved for smart textiles is the high electric resistance inherent in transporting current from the generator to the actuator elements, problem due to the high internal resistance shown by a textile material.

Another apparent problem is the air tightness and water resistivity of the integrated components. Indeed the materials constituting most electronic equipments, neither absorb liquids nor are protected from them and in any case they are not adapted to be contacted by liquids. Therefore said components may be easily damaged by water or other liquids, once they are integrated into the printed circuit board.

Thus it is clear that the advantages desired by molding or printing circuits on textiles, cannot be attained in view of the physical features of the circuits.

Further problems in implementing efficient and performing electrotextiles are bound by the operative temperatures. Indeed the electronic components need weldings to be wired, made at an average temperature in the range between 200° C. and 3500°, while most textiles cannot withstand thermal stresses above 200° C., so that it is not possible to make a junction or welding between a fabric and such a circuit.

It is however true that nowadays the introduction of mobile devices and miniaturized electronic equipments allowed a first development of this technology, leading to develop guide fibers for headphones. This article however is limited to clothing for youngsters with few applications of interest for scientific or technical purposes.

Still in the clothing industry, electronic devices were directly integrated in the fabrics used for garments. This was possible by using electric wires made of special metal fibres woven together with the traditional textile fibres, allowing passage of small currents and signals, giving the possibility of inserting inside the article of clothing, an MP3 reader or a small control keyboard.

However, this does not mean that the textile industry and the electronic industry found the right solution to integrate said technologies, but for the time being they succeded only to combine in a simple and functional way two industrial products coming from different fields, trying to optimize as much as possible the above mentioned limitations, which were not yet overcome.

With a more specific insight of the relevant technology, the prior art conducted some studies, especially to improve the development of smart textiles or rfid antennas and to obtain a greater versatility in implementing a printed electronic circuit, about designing devices on paper or polymeric materials having reduced thickness and dimensions, which however do not remove the above mentioned problem of space and poor versatility.

There were still many examples to be cited, but in few words the problems of the electro-textile printing are mostly defined in the wide portion dedicated to the discussion of prior art products which were brought to the attention of the technicians skilled in this field, but did not reach as yet a good technical and functional quality nor and adequate reliability standard.

It is also useful to point out that, also in this field, the electronic technology used is based on known physical principles, according to which it is essential to have a well defined control on the dimensions and parameters of track length and thickness. The results of several tests led to the recognition of several problems. Among those mostly detected about printing on textile materials, fragmentation of the path and difficulty for the materials to be printed of adherence to the receiving fabric.

### SUMMARY OF THE INVENTION

Therefore an object of the present invention is to develop a method of direct printing on textile materials, removing the previously detected drawbacks, thus allowing deposition of conductive materials on textiles such as polyesters, cotton, polyester-cotton mix and non-woven fabric.

Another object of the present invention is to develop a method of printing electro-textile composite fabrics, adapted to make various kinds of circuits for different purposes, such as printing of electric circuits, e.g. with magnetic effect or for transmission and reception of signals of any kind.

What the present invention puts as its target in a particularly inventive way, is to achieve a true integrated electro-textile system, namely a system in which the textile fiber acts as sensor or actuator.

Another object of the present invention is an innovative method of electronic printing by screen printing or ink-jet technology.

Still another object of the present invention is a process to be implemented by using proper components, allowing to print various types of electro-textile fabrics, suitable for a plurality of applicative objects.

A further object of the present invention is to achieve systems of textile sensors that can transmit and receive wifi signals.

Still a further object of the present invention is to achieve systems of medical sensors, electroluminescent systems and further systems that will be described hereinafter.

In order to achieve the above mentioned objects, the textile product should be provided with self-supported active functions, and the electronic system should be embedded inside the fabric.

There are some materials provided with electronic functions, that the technologies now available on the market, can supply for these objects.

For instance to make smart clothes, an innovative method is disclosed, involving use of a new technology, adapted to integrate and combine electronic products with the fibres. In other words, the result of the process according to the present invention may be defined in short as the production of an electro-textile interface.

More particularly, the present invention exploits the screen printing method for the electro-textile printing; although this method was already used, it did not achieve useful results. It is well known that the screen printing technology is used to print traditional electronic circuits on rigid supports, such as silicium bases, or polymeric flexible supports, to make conductive tracks for the electric current. It is also well known that the same screen printing technology allows to obtain images and illustrations on textiles for ornamental purposes.

Through innovations in the field of conductive inks and the know-how of both fields, it was possible to achieve a new process to deposit conductive material on textile and flexible supports.

It is to be pointed out that each preferred embodiment of the present invention describes different applications using the same method, and each application comprises use of adequate materials, which however may change according to the applicative environment. The present invention will now be described in various preferred embodiments, all based on the same method, but for different objects, and using different materials, but all useful for the purpose of the process hereinafter described.

In any case, each embodiment of the present invention described herein comprises a screen printing method using particular materials and processes to make an electro-textile fabric, capable of transmitting electric pulses and signals of any kind.

By using this innovative technological process it is possible to solve many of the above mentioned problems, through devices and steps that will be described hereinafter, by means of a multilayer deposit on the selected support by the screen printing method, of the conductive track which is deposited directly on the fabric or after spreading either a primer or dielectric material, or both primer and dielectric material.

The advantage of a multilayer deposit, besides improving the global features of the electronic circuit, and the transmission of microcurrents inside the substrate, is to obtain a homogeneous basis for spreading the conductive track, thus warranting the perfect adhesion on the substrate and the dimensional control of the conductive track section. In this way it is possible to make electronic circuits with physical characteristics similar to the normal circuits printed on rigid or flexible support.

For instance document U.S. Pat. No. 6,395,121 discloses a multilayer obtained by overprinting several times the conductive material, until circuit resistivity is sufficient for the functions therein described; however such a technique is not always efficient and in any case is clearly expensive, besides causing problems of resistivity and noise inside the circuit.

### BRIEF DESCRIPTION OF THE DRAWINGS

These and other advantages achieved by the present invention, as well as more specific details will be hereinafter described and become apparent by reading the following detailed description of some preferred embodiments, to be considered by making reference to the annexed sheets of drawings, in which:

FIG. 1 shows an embodiment of the process of screen printing of a multilayer applied on a substrate;

FIG. 2 shows a detail of FIG. 1, where the arrangement of the various layers of material on the textile substrate is highlighted;

FIG. 3 shows a different embodiment of the process of screen printing of a multilayer applied on a textile substrate;

FIG. 4 shows a further embodiment of the process of screen printing of a multilayer applied on a textile substrate; and

FIG. 5 shows a further embodiment of the process of printing with the ink-jet method of a multilayer applied on a textile substrate.

### DETAILED DESCRIPTION OF THE PREFERRED EMBODIMENTS

More particularly, the figures of the accompanying drawings show different embodiments and screen printing stages according to the present invention. For the printing process, electrically conductive, thermoelectric or electroluminescent materials are used. These materials are applied by means of screen printing technology on textile substrates of various kinds, preferably polyesters, cottons or non-woven fabrics.

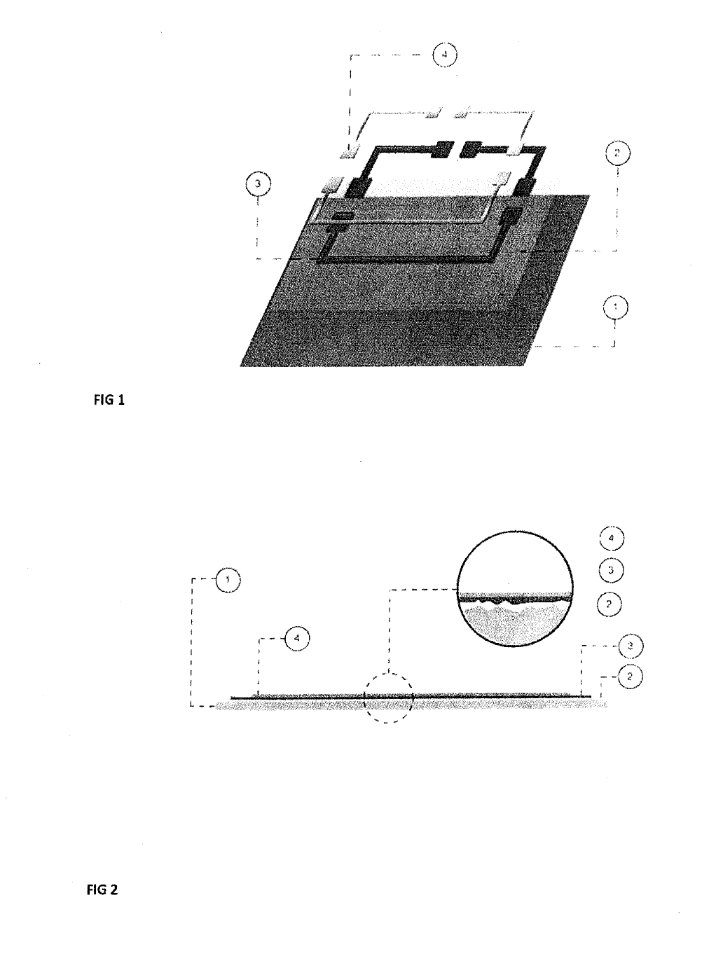

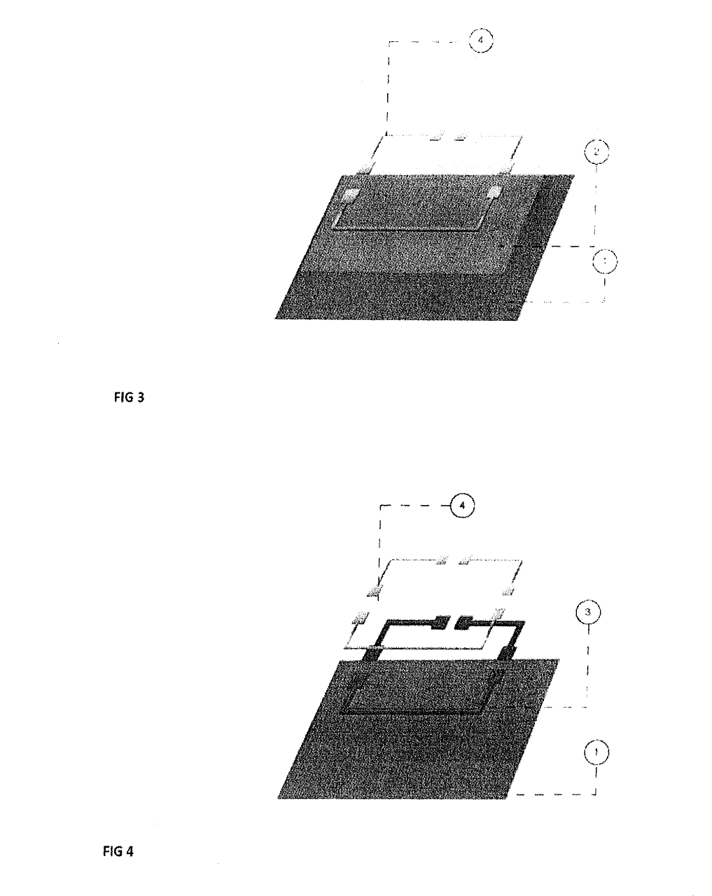

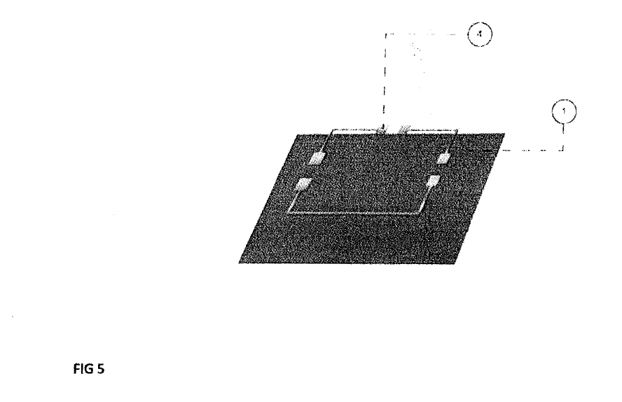

As shown in the drawings, the deposit of the electrically conductive, thermoelectric or electro-luminescent material may be effected for instance on a multilayer consisting of primer and dielectric material (FIG. 1), on a layer of primer only (FIG. 3), on a layer of dielectric material only (FIG. 4) or directly on the textile substrate by the ink-jet method (FIG. 5). Each combination provides for different capacity of current resistance inside the printed circuit.

As shown in FIGS. 1 and 3, the deposit of the primer layer 2 takes place through the method of atomized spray with manual or semi-automatic equipment. Type of primer 2 used is varying according to the substrate on which it is applied. Once the primer film 2 is deposited, it may be dried with a thermal treatment at 200° C. in a hot air circulation oven, with an advancement speed of about 5 m/min. Alternatively it is also possible to treat primer 2 with thermal pressing at 180° C. for about 30-60 seconds, by means of a suitable thermal press.

The deposit of the dielectric layer 3, as shown in FIGS. 1 and 4, takes place through the screen printing method with manual, semiautomatic or automatic in-line equipment or rotational equipment for roll printing. The types of usable sieves are single thread polyester 61T/HD (final thickness about 25 μm), 77T/HD (final thickness about 18 μm), 120T/HD (final thickness about 10 μm) or stainless steel 77-110 T/HD. The type of sieve suitable for deposition of material is polyurethane 70-75 Durometer allowing a thickness of emulsion of 20-40 μm. An example of a useful material is the product Electrodag 452ss (trade name) of the company Acheson Colloiden B. V. (Henkel Group), but in any case in the preferred embodiments, use of traditional water or solvent based screen printing pastes is preferred.

Once deposited, the dielectric material 3 may be immediately cured by UV lamps of 80 W/cm or 120 W/cm, or UV nitrogen ovens of 40 W/cm.

At the end of the substrate curing stage, the electrically conductive material 1, which may be silver or even aluminium or copper based thermoelectric or electro-luminescent material, may be arranged on insulated support, again using a screen printing process. An example of a useful material to this purpose is the product Electrodag pf-410 (trade name) of the company Acheson Colloiden B. V. (Henkel Group).

It is to be noted that the deposit of said layer of electrically conductive material 1, like for the dielectric material 3, takes place by use of the screen printing method with manual or semiautomatic equipment or roll printing machine. The types of usable sieves are of single thread polyester 68-110 T/HD or stainless steel 90-154 T/HD, allowing to achieve a dry thickness of 8.12 μm. The type of sieve suitable for the material deposit is polyurethane 70-75 Durometer allowing an emulsion thickness of 20-40 μm.

Once deposited, the dielectric material 3 may be cured at a temperature between 80° C. and 140° C. Viscosity of the dielectric material 3 is varying between 10,000 and 25,000 mPa·s for a density of about 2500 kg/m³.

More particularly, it is to be noted that the used conductive materials are preferably carbon based resistive pastes, carbon based thermoresistant screen printing pastes or electro-luminescent pastes too. Each of these pastes is essential to obtain specific technical solutions directly in the material deposit stage, which will be described in the following examples.

The combined application of a primer layer 2 and a dielectric layer 3, as shown in FIG. 2, allows a higher reduction of the circuit resistance. The deposit of the primer film 2 on the textile support, allows to level the gaps between weft and warp of the fabric.

The deposit of the dielectric material 3 on the first layer of primer 2 fosters generation of a basic insulating layer on which the electrically conductive material 4, e.g. of thermoelectric or electroluminescent type, is applied.

The resistance of the electrically conductive material 4 is less than 0.025 Ohm² at 25 μm. If the electrically conductive material 4 is applied directly on the textile substrate, as shown in FIG. 4, the value of the resistance increases of 30%-35%, and is reduced of 16-22% if on the contrary said electrically conductive material 4 is applied on a primer film (FIG. 3), and reduced again of 4%-12% if said material is deposited on a dielectric film (FIG. 4), and finally the resistance is reduced of 1%-6% If said electrically conductive material 4 is applied on a double layer of primer and dielectric as shown in FIG. 1. More particularly, a double application of substrates is effected to optimize the closure of pores between weft and warp.

It is fundamental to point out that one of the factors making this process very innovative and advantageous, is that the process may take place by using the herein cited exemplary pastes on textile supports of different kind. The obtained results have proved that each of the described embodiments is functional and performing, thus said process allows to carry out different applications and to obtain new technological solutions.

In addition, it is to be noted that the main difference with the existing technologies was clear since the first tests of this process. Indeed, since the very first tests, it was found that using this method, passage of microcurrents in electronic circuits printed on textile substrates, was measured with determined reproducible and controllable physical characteristics. These tests confirmed the possibility of making a high number of geometric shapes with verifiable characteristics. Starting from the resistivity data, it is possible to obtain all the track dimensions, so as to design the electric circuit with the same rules of the prior art, a factor that was not possible to use with the known silver fibers woven inside textiles. Checks effected with proper testers confirmed that the values of theoretical resistance were identical to those found in the practical tests. Therefore this process may be used to make any kind of circuit with any kind of projected track. It is also to be pointed out that the connection of rigid electronic components, such as resistors, transistors, diodes, relays, capacitors, integrated circuits and other possible suitable components, with the textile fabric is obtained by deposition of conductive adhesives for temperature sensitive substrates.

Just for exemplary purposes, it is also to be noted that, in the field of the textile printing, it is important that the paste components, such as dielectric, conductive, resistive, thermoresistant and/or electroluminescent pastes, are certified as to safety requirements, according to the existing regulations. These pastes should therefore be adequate for use on textiles directly in contact with the human body, and this is particularly important for silver based conductive tracks.

The fabric used for example is preferably polyester, cotton, cotton-polyester mix on non woven fabric. Use of a polyester fabric is advantageous because it has a limited elasticity, so that it is possible to combine it with the electrically conductive material also having a limited elasticity and this similarity of behaviour allows to obtain advantageously a high operative reliability.

It was found that said electrically conductive elastic material should preferably contain silver particles in a polymer based binder such as polyurethane. These silver particles may be included in a silver paste, which is applied on the fabric by screen printing. The silver paste forms an elastic path, where the silver particles are at least partially responsible for the electric conductivity of the path. As an alternative to silver paste, it is also possible to use some inks and/or pastes based on copper compounds or carbon, such as carbon nanotubes, or aluminum based pastes, according to the desired result.

Some examples of preferred embodiments of the present invention, in which the applicative process was used are the following:
Biomedical field, to make sensors a paste with high silver contents is used on graphic dielectric support and a primer layer, to reduce to a minimum the track resistivity and maintain a high material flexibility.
RFID Sector, to make low performing antennas (i.e. with a reading range of few centimeters), a dielectric base and a graphite based conductive material are used (carbon nanotubes). On the contrary, for performing antennas with broad reading range, use of silver pastes is required.
Touch textiles sector (clothing, furnishings and traditional electronics).

Preferably as a primer a layer of plastisol or like product is used. If touch is resistive, it operates very well by using a conductive layer either silver or graphite based. In case of capacitive touch, silver based conductive pastes are preferably used.
For lighting clothes, screen printing plastisol is preferably used as a base, preferably silver paste for conductive elements; if a technology without plastisol is used, a dielectric paste for the insulating layers and an electroluminescent paste for the bridges are used.
For electro-heating clothes, for instance screen printing plastisol as a base, silver paste for the conductive tracks and electro-heating paste for the heating resistors are used.

More particularly, going into details, the process of the present invention comprises the following steps:
a) sizing the fabric or unwinding of the roll;
b) spreading the primer by spraying it;
c) heat setting the primer by passage in oven or press (200° C.×5 min in oven or 170° C.×90 sec under press);
d) printing of the plastisol insulating layer (broad mesh sieve with soft doctor blade;
e) drying the insulating plastisol layer in oven (200° C.×2 min);
f) depositing the conductive layer (sieve with narrower mesh);
g) curing in oven (variable according to material, but approximately 15-30 min at 150°-200° C.); in case of application of component, welding takes place by means of conductive pastes or films;
h) printing of insulating layer, again by screen printing (plastisol as material) or PVC hot pressing.

Between each step, all centering and feeding operations required by screen printing technology are obviously carried out.

It was found that this process, carried out by using a screen printing procedure with dielectric materials, gives the possibility of coupling rigid elements on textile supports in a structural way, by using conductive pastes adhering to the fabric at quite low temperatures, thus particularly suitable for textiles. It was also found that embedding chips (such as traditional integrated circuits with standard pins) for instance in a felt element, it is possible to connect non only the conductive tracks, but also the textiles with one another.

The printed textiles obtained with the above described process are advantageously very flexible, the conductive paste is not being torn when handling the fabric, and moreover it was found that by coupling fabric with dielectric base layer (preferably but not necessarily with upper insulation), these electro-textiles produced in this way can be washed without problems.

### Example 1

An example of preferred embodiment of the invention, which resulted to be particularly performing, is given herein for illustrative purposes only, relates to RFID antennas, currently very popular in many commercial, scientific and industrial sectors, RFID antennas for the biomedical environment were produced with the process of the present invention with the following steps:
Working station with four areas and rotary carousel;
Start from cotton jersey (135 grams combed);
Centering frames for layer overlapping;
making plastisol dielectric layer with antenna base;
drying under IR hood for few seconds;
making the silver based conductive layer with antenna geometry according to plan;
curing in a static oven;
spreading conductive welding paste only on connection points of the RFID chip;
micropositioning of chip by pick-and-place system;
curing the conductive welding paste in oven;
applying a first PVC layer only on the chip welding point;
applying insulation with thermowelding PVC on the entire antenna geometry.

Following this innovative procedure, on RFID antenna is obtained directly on the T-Shirt or vest. It is also possible to make these antennas on textile pieces or rolls and then make up the article of clothing subsequently in order to reduce the production times; recent tests proved that it is possible to make also on the other side of the piece, a screen printing track of thermoadhesive material and then apply under heat the piece on the finished articles.

This RFID antenna may be applied at any desired point on the vest or shirt, that once worn by the patient, contains codes referring the medical operators back to his case sheet, thus enabling to take immediate action by querying the patient's vest or shirt with a portable rfid reader. Moreover, positioning a number of antennas inside the hospital, it will be possible to monitor the patient's movements and in case of attack, find immediately his position within the hospital area.

### Example 2

Another example of preferred embodiment of the invention, demonstrating the effective versatility of the described process, is the following model of a touch system to be applied for furnishings.

The process was carried out on the reverse side of a textile fabric with medium/fine texture and consisted of three main parts.

A)—Working of Fabric Piece
centering of screen printing frames;
printing of first plastisol dielectric layer (wide mesh frame);
drying under IR hood (about 60 sec at 150° C.);
possible repeating of passage until the mesh is fully covered;
printing of conductive track, silver or graphite based; when the track is not sufficiently thick, it is possible to repeat passage before curing the paste in oven;
actuating motion of the screen printing carousel to cure the conductive paste in a static oven (30 minutes at 150° C.)

B)—Parallel Manufacture of Textile Connectors
sizing of fabric (polyester or cotton with thin waterproof or absorbing mesh);
centering of screen printing frames;
printing of first plastisol dielectric layer (wide mesh frame);
drying under IR hood (about 60 seconds at 150° C.);
pringing of silver based conductive track;
curing of conductive paste;
Insulation of conductive track by thermal pressing of thermoadhesive PVC (leaving open the connection areas at the ends of the connector);

C)—Assembly
Welding of one end of the connector on an area of the touch sensor prepared during the printing stage;
spreading the conductive welding paste;
drying in oven (5 to 30 minutes at 100° C.);
closure of the welding area with PVC thermally welded under hot plate.

On the second portion of the connector a (standard) copper wire is mounted with a molten tin terminal, allowing to interface with the electronic card controlling the signals (buried into the sofa stuffing);
the copper portion of the wire is opened and welded, again with a conductive welding paste;
the whole is then insulated with thermoadhesive PVC under press.

Once the elements are connected, the fabric is mounted on the sofa shoulder and connected to the electronic boards inside the stuffing.

It is also possible to carry out this procedure also on an outer lighter fabric and insert the touch member between the outer fabric and the stuffing of the sofa.

Temperature ranges and settings.
From the tests conducted it was noted that temperature and drying time heavily affect the track inner resistivity. Indeed:
Already with Shock or Flash treatments of 2 minutes at 200° C. high values of conductivity but with track resistivity;
With treatments at temperatures around 100-150° C., 15 to 30 minutes are required to reach a resistivity of 0.025 sq/ohm;
At higher temperatures, time is reduced, at 180° C. time is 10 to 15 minutes for a complete polymerisation;
At lower temperatures, time is increased, at 75-90° C. at least 30 minutes are required for a complete polymerisation;

The definition of the temperature range is variable, depending upon the type of substrate on which printing occurred, the thickness of the printed track and the track length.
Studies in depth were also conducted on the value of silver concentration in the conductive track and the results were as follows:
Increasing the silver quantity, the track once cured tends to be stiffer but practically without resistivity;
Reducing the silver quantity, the track is more flexible but the resistivity is higher.

It is recommended not to reduce the quantity of nanoparticled silver inside the track under 60%. Pastes with percentages even of 95% of silver may be obtained.

Moreover, a further embodiment of the process according to the present invention comprises the alternative use of ink-jet printers, exploiting the last generation inks known to the person skilled in this art, then it will be possible to make microwledings using micrometric pick-and-place similar to the above cited ones, to reduce the size of the rigid components. In practice, if the component has a micrometric size, the assembled textile will have a rigidity close to zero.

### INDUSTRIAL APPLICABILITY

It is clear that the process according to the present invention is still more advantageous, because it allows to manufacture said electro-textiles at a very low cost, with performances of really high quality.

Said innovative technology has very wide ranges of possible applications, and herein below some fields of application are indicated in an explanatory but not limiting way, where the process may have a fundamental role.

For instance, said process is leading to the implementation of thin, easy to be handled electro-textiles, stress resistant and that can be washed under certain conditions, and may be particularly useful for instance in the following fields (including those already listed in some preceding paragraphs):

Biomedical, e.g. to make textile sensors, patient monitors, wifi transmission of data acquired by electro-textiles, smart clothes and EEG systems.

Automotive, for seats with driver's recognition (detection of his parameters such as weight, posture, textile control pad, start of electronic devices, e.g. by pressing a finger on the armrest fabric.

RFID systems, e.g. checking entrance in shops, warehouses, monitoring workers, site security and safety, industrial laundries, integrated toll houses, automatic help systems;

Electronic circuitry, such as textile microprocessors, robot electronics, iperflexible connectors.

Furnishing, e.g. sofa keyboards, domotics, lamp switches, touch lighting devices.

Clothing, sport sensorized shirts, integrated MP3 readers, military monitoring systems, position controls, gps signal integration.

Materials: new composites with integrated printed (not embedded) electronics.

All the above proposed applications involve implementation of innovative devices, less prone to failure and low cost. In all the embodiments of the process, the rigid, flexible or textile components may be assembled directly in the textile substrate by conductive welding pastes.

It is to be noted that it is possible to use magnetic or resistive screen printing pastes for suitable preferred embodiments of the invention, which together with the conductive, dielectric, electroluminescent and thermoresistant pastes, are very important to obtain e.g. flexible textile resistances, microprocessors and integrated antitampering and shop lifting systems.

These and other alternative embodiments, still obtained by the innovative method of the present invention, are in any case to be considered falling within the scope of the present invention, even when related to different applicative environment, as defined in the appended claims.

1. A method of printing electronic systems on textile substrates (1) by screen printing, comprising the use of primers, insulating materials such as dielectrics (3), conductive materials (4), resistive materials, magnetic materials, electroluminescent materials, thermoelectrical materials and electronic components, and comprising the following steps:
a) sizing the textile substrate (1) or unwinding a textile roll;
b) spraying the primer (2) on the textile substrate, to level the gaps between warp and weft of the textile substrate (1);
c) heat setting the primer (2) by passage through a hot oven or a hot press;
d) printing the insulating layer of dielectric material (3) having thickness range from 10 to 25 μm;
e) drying the insulating layer in the oven;
f) depositing the conductive layer (4) with a dry thickness of 8 to 12 μm, getting a frame having a finer mesh;
g) curing in oven of variable duration depending on the material, variable between 15-30 minutes at temperatures varying between 150°-200° C.; and
h) printing an insulating layer, again by screen printing, or thermopressing by heat press to isolate the traces.

2. The method of claim 1, wherein after the polymerisation stage, in case of application of traditional hard or electronic components or smd, flexible polymeric components and textile components, these are welded by means of conductive pastes or films to the textile substrates.

3. The method according to claim 1, further comprising, in each phase, operations of centering and feeding proper of screen printing.

4. The method according to claim 3, wherein ink-jet technology is also used as an integration or support for deposition.

5. The method according to claim 1, wherein the conductive layer (4) is deposited directly on the textile support without intermediate layers printed by ink-jet printing.

6. (canceled)

7. The method according to claim 1, wherein said textile substrate (1) is preferably a tissue, for example polyester or cotton, or cotton-polyester or non-woven tissue.

8. The method according to claim 1, wherein after the application of a first layer of primer (2) a second layer of dielectric (3) is applied, for example plastisol for screen printing, screen printing water-based pastes, or technical dielectrics.

9. The method according to claim 1, wherein after the application of a first layer of primer (2), a conductive layer (4) is applied, which can be a magnetic, resistive, thermal or electro-luminescent one.

10. The method according to claim 8, wherein said layers of primer (2), dielectric (3) and conductive layer (4), magnetic, resistive, thermal or electro-luminescent, are printed by screen printing.

11. The method according to claim 1, wherein said electrically conductive materials, include, for example particles of copper, or silver, or carbon and aluminum nano tubes.

12. The method according to claim 1, wherein said electroluminescent materials, thermo-resistive materials, magnetic or resistive materials, are applicable in form of screen printing paste.

13. The method according to claim 1, wherein rigid components, flexible components, or textiles can be assembled directly into the textile substrate by using conductive welding paste, or welding films.

14. Electro-textile interface comprising electronic systems printed on textile substrates produced by the method according to one or more of the preceding claims.

15. The method according to claim 1, wherein a double application of substrates is effected for the closure of pores between weft and warp.

16. The method according to claim 9, wherein said layers of primer (2), dielectric (3) and conductive layer (4), magnetic, resistive, thermal or electro-luminescent, are printed by screen printing.
